(19) United States
(12) Patent Application Publication
(10) Pub. No.: US 2024/0039431 A1
(43) Pub. Date: Feb. 1, 2024

(54) DEPOSITION APPARATUS AND DRIVING METHOD THEREOF

(71) Applicant: Samsung Display Co., LTD., Yongin-si (KR)

(72) Inventors: Jun Hyeuk KO, Yongin-si (KR); Min Goo KANG, Yongin-si (KR); Suk Ha RYU, Yongin-si (KR); Min Seok KIM, Yongin-si (KR); Eui Gyu KIM, Yongin-si (KR); Min Chul SONG, Yongin-si (KR); Young Sun CHO, Yongin-si (KR)

(73) Assignee: Samsung Display Co., LTD., Yongin-si (KR)

(21) Appl. No.: 18/107,049

(22) Filed: Feb. 8, 2023

(30) Foreign Application Priority Data
Jul. 27, 2022 (KR) 10-2022-0093502

(51) Int. Cl. H02N 13/00; C23C 14/04; C23C 14/50

(52) U.S. Cl. CPC H02N 13/00; C23C 14/042; C23C 14/50

(57) ABSTRACT

A deposition apparatus includes a plate; electrostatic chucks including a first surface on which the plate is disposed; and a second surface on which a substrate is supported; and a control device that controls a flatness between the electrostatic chucks, and each of the electrostatic chucks includes driving shafts disposed through an area of an edge of the first surface of each of the electrostatic chucks, and the control device controls the flatness between the electrostatic chucks through the driving shafts by measuring a height deviation between the electrostatic chucks.

### CROSS-REFERENCE TO RELATED APPLICATION(S)

This application claims priority to and benefits of Korean Patent Application No. 10-2022-0093502 under 35 U.S.C. § 119 filed in the Korean Intellectual Property Office on Jul. 27, 2022, the entire contents of which are incorporated herein by reference.

### BACKGROUND

### 1. Technical Field

The disclosure relates to a deposition apparatus and a driving method thereof.

### 2. Description of the Related Art

Recently, electronic devices such as smart phones, tablets, notebook computers, and smart televisions have been developed. These electronic devices include a display device to provide information. The display device may be manufactured by repeating several times a thin film deposition process for forming a thin film of a material on a surface of a substrate, a photo-lithography process for exposing a selected portion of the thin film, and a dry or wet etching process for patterning into a desired shape by removing the exposed portion of the thin film, and the thin film deposition process, the dry etching process, and the like thereof are usually carried out in a closed process chamber, and an electrostatic chuck for fixing the substrate, a cooler for controlling the process temperature, and the like may be provided in each process chamber.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

One object of the disclosure is to provide a deposition apparatus capable of maintaining a flat shape of an electrostatic chuck for fixing a substrate.

Another object of the disclosure is to provide a driving method of a deposition apparatus for controlling a flatness between electrostatic chucks so that the electrostatic chucks can maintain a flat shape.

It should be understood, however, that the objects of the disclosure are not limited to the objects described above, and various changes and modifications may be made without departing from the spirit and scope of the disclosure.

A deposition apparatus according to embodiments may include a plate; a plurality of electrostatic chucks including a first surface on which the plate is disposed; and a second surface on which a substrate is supported; and a control device that controls a flatness between the plurality of electrostatic chucks, wherein each of the plurality of electrostatic chucks may include a plurality of driving shafts disposed through an area of an edge of the first surface of each of the plurality of electrostatic chucks, and the control device controls the flatness between the plurality of electrostatic chucks through the plurality of driving shafts by measuring a height deviation between the plurality of electrostatic chucks.

According to an embodiment, the plurality of electrostatic chucks may include a first electrostatic chuck, a second electrostatic chuck, and a third electrostatic chuck spaced apart from each other in a first direction, and the first electrostatic chuck and the third electrostatic chuck may include a metal material, and the second electrostatic chuck may include a ceramic material.

According to an embodiment, the first electrostatic chuck, the second electrostatic chuck, and the third electrostatic chuck may support the substrate including a center area and an edge area surrounding the center area, and the plurality of driving shafts may be disposed on the first surface of each of the first electrostatic chuck, the second electrostatic chuck, and the third electrostatic chuck corresponding to the edge area of the substrate.

According to an embodiment, the plurality of driving shafts may include a first driving shaft, a second driving shaft, a third driving shaft, and a fourth driving shaft, and the third driving shaft and fourth driving shaft disposed on the first electrostatic chuck and the first driving shaft and the second driving shaft disposed on the third electrostatic chuck may be adjacent to the second electrostatic chuck.

According to an embodiment, the first electrostatic chuck may further include a fifth driving shaft disposed between the first driving shaft and the second driving shaft, and the third electrostatic chuck may further include a sixth driving shaft disposed between the third driving shaft and the fourth driving shaft.

According to an embodiment, the deposition apparatus may further include: a mask frame disposed in an area corresponding to the edge area below the substrate; and a deposition mask corresponding to the center area below the substrate.

According to an embodiment, the deposition apparatus may further include a transfer unit that is connected to an area of the plate corresponding to the center area of the substrate and that controls a vertical movement of the plurality of electrostatic chucks, wherein the plurality of driving shafts pass through at least a portion of the plate while avoiding an area that includes the transfer unit.

According to an embodiment, each of the plurality of driving shafts may be individually driven by the control device.

According to an embodiment, each of the plurality of electrostatic chucks may further include a sensor exposed through the second surface of the plurality of electrostatic chucks, the sensor may detect a contact with the substrate, and the control device may measure a height deviation between the plurality of electrostatic chucks based on a contact order with the substrate with respect to each of the plurality of electrostatic chucks.

According to an embodiment, the control device may control the plurality of driving shafts so that the plurality of electrostatic chucks are spaced apart from each other by a same distance based on a surface of the plate based on the height deviation between the plurality of electrostatic chucks.

A driving method of a deposition apparatus according to embodiments may include disposing a substrate on a surface of a plurality of electrostatic chucks; measuring a height deviation between the plurality of electrostatic chucks; and controlling a flatness between the plurality of electrostatic chucks through a plurality of driving shafts disposed on each of the plurality of electrostatic chucks based on the height deviation between the plurality of electrostatic chucks, wherein the plurality of driving shafts are disposed in an area of an edge of another surface of the plurality of electrostatic chucks facing the surface of the plurality of electrostatic chucks.

According to an embodiment, each of the plurality of electrostatic chucks may further include a sensor disposed on the surface of the plurality of electrostatic chucks, and the measuring of the height deviation between the plurality of electrostatic chucks may include: detecting a contact with the substrate with respect to each of the plurality of electrostatic chucks through the sensor; and determining the height deviation between the plurality of electrostatic chucks based on a contact order with the substrate with respect to each of the plurality of electrostatic chucks.

According to an embodiment, the plurality of driving shafts disposed on each of the plurality of electrostatic chucks may be individually driven in the controlling of the flatness between the plurality of electrostatic chucks.

According to an embodiment, the plurality of driving shafts may be disposed between the plurality of electrostatic chucks and a plate, and a distance between the plurality of electrostatic chucks from the plate may be equally controlled through the plurality of driving shafts in the controlling of the flatness between the plurality of electrostatic chucks.

According to an embodiment, the plurality of electrostatic chucks may include a first electrostatic chuck, a second electrostatic chuck, and a third electrostatic chuck spaced apart from each other in a first direction, and the first electrostatic chuck and the third electrostatic chuck may include a metal material and the second electrostatic chuck may include a ceramic material.

According to an embodiment, the substrate including a center area and an edge area surrounding the center area may be absorbed by applying a voltage to the first electrostatic chuck, the second electrostatic chuck, and the third electrostatic chuck in the disposing of the substrate on one surface of the plurality of electrostatic chucks.

According to an embodiment, the plurality of driving shafts may be disposed on the another surface of each of the first electrostatic chuck, the second electrostatic chuck, and the third electrostatic chuck corresponding to the edge area of the substrate.

According to an embodiment, the plurality of driving shafts may include a first driving shaft, a second driving shaft, a third driving shaft, and a fourth driving shaft, and the third driving shaft and the fourth driving shaft disposed on the first electrostatic chuck and the first driving shaft and the second driving shaft disposed on the third electrostatic chuck may be adjacent to the second electrostatic chuck.

According to an embodiment, the first electrostatic chuck may further include a fifth driving shaft disposed between the first driving shaft and the second driving shaft, and the third electrostatic chuck may further include a sixth driving shaft disposed between the third driving shaft and the fourth driving shaft.

According to an embodiment, the driving method may further include moving the substrate to be adjacent to a deposition mask corresponding to the controlling of the flatness between the plurality of electrostatic chucks.

The deposition apparatus and the driving method thereof according to embodiments can prevent the electrostatic chucks from sagging in a gravitational direction by fixing the substrate through a plurality of electrostatic chucks, thereby fixing the substrate in a flat state without deforming a shape. Also, the deposition apparatus and the driving method thereof can measure a height deviation between the plurality of electrostatic chucks and compensate for the height deviation between the plurality of electrostatic chucks through a plurality of driving shafts included in the plurality of electrostatic chucks, thereby controlling the flatness between the plurality of electrostatic chucks. As a result, the process of treating the substrate may be performed while the substrate is maintained in a flat state regardless of a change in process conditions.

The deposition apparatus and the driving method thereof according to embodiments may prevent mass production of defective substrates or poor quality substrates due to an error with respect to the flatness of the substrate in the process of treating the substrate.

It should be understood, however, that effects of the disclosure are not limited to the effects described above, and various changes and modifications may be made without departing from the spirit and scope of the disclosure.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view schematically illustrating a deposition apparatus according to embodiments.

FIG. 2 illustrates configurations of the deposition apparatus of FIG. 1.

FIG. 3 is a drawing illustrating an example of a substrate of FIG. 1.

FIG. 4 illustrates an example of a plurality of electrostatic chucks of FIG. 1.

FIG. 5 illustrates an example of a plurality of electrostatic chucks of FIG. 1.

FIG. 6 is a drawing for illustrating a method of controlling flatness of a plurality of electrostatic chucks of FIG. 1.

FIG. 7 is a flowchart illustrating a driving method of the deposition apparatus of FIG. 1.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, sizes, thicknesses, ratios, and dimensions of the elements may be exaggerated for ease of description and for clarity. Like numbers refer to like elements throughout.

In this specification, when one component (or area, layer, part, etc.) is referred to as being “on,” “connected to,” or “coupled to” another component, it means that one component may be directly connected/coupled on the other component, or a third component or other component or components may be disposed therebetween.

It will be understood that the terms “connected to” or “coupled to” may include a physical or electrical connection or coupling.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

The terms, ‘first’, ‘second’ and the like may be used for description of various constituent elements, but those meanings are not necessarily limited. The above terms are used only for distinguishing one constituent element from other constituent elements. For example, a first constituent element may be referred to as a second constituent element and similarly, the second constituent element may be referred to as the first constituent element herein and within the scope of the appended claims.

As used herein, the singular forms, “a,” “an,” and “the” are intended to include the plural forms as well, unless the context clearly indicates otherwise.

Terms such as “under”, “below”, “on”, “above”, and the like are used to describe the relationship of elements shown in the drawings. These terms are a relative concept and are made on the basis of the direction/directions shown in the drawing or drawings but are not limited thereto.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a deposition apparatus and a driving method thereof according to an embodiment will be described with reference to the drawings.

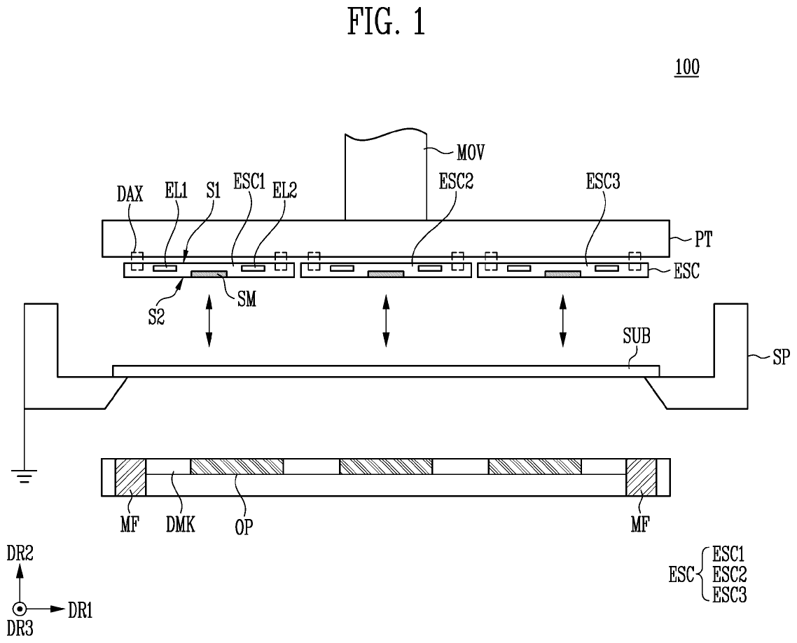

FIG. 1 is a schematic perspective view schematically illustrating a deposition apparatus according to embodiments.

Hereinafter, a direction crossing (or intersecting) a plane defined by the first and second directions DR1 and DR2 may be defined as the third direction DR3. The third direction DR3 may substantially perpendicularly cross (or intersect) the plane defined by the first and second directions DR1 and DR2. In this specification, a meaning of “in a plan view” may mean a state viewed in the third direction DR3.

Referring to FIG. 1, the deposition apparatus 100 may include a plate PT, a plurality of electrostatic chucks ESC, a plurality of driving shafts DAX, a sensor SM, a deposition mask DMK, and a transfer unit MOV.

In an embodiment, the plate PT may support a plurality of electrostatic chucks ESC. A plurality of electrostatic chucks ESC may be connected or coupled to one surface or a surface of the plate PT. The plate PT may include, for example, ceramic or metal.

In an embodiment, the plurality of electrostatic chucks ESC may include a first surface S1 on which the plate PT is disposed and a second surface S2 on which the substrate SUB is supported.

In an embodiment, the plurality of electrostatic chucks ESC may chuck or dechuck the substrate SUB in the deposition process by forming an electrostatic force using an electrostatic induction phenomenon. In an embodiment, the plurality of electrostatic chucks ESC may chuck the substrate SUB to perform a process of treating the substrate SUB, and after the substrate SUB is processed, the plurality of electrostatic chucks ESC may dechuck it for processing in a next step, and this process may be repeated.

In an embodiment, the substrate SUB may be supported by a substrate supporter SP. The substrate SUB may include a metal layer, and be connected to a ground terminal. The metal layer of the substrate SUB may include wires and pads to be connected to the wires. In an embodiment, in case that the substrate SUB is dechucked from the plurality of electrostatic chucks ESC, it may be supported by the substrate supporter SP. The substrate SUB may be grounded through the ground terminal.

In an embodiment, each of the plurality of electrostatic chucks ESC may include a first electrode EL1 and a second electrode EL2. The first electrode EL1 and the second electrode EL2 may be spaced apart from each other in the first direction DR1.

In an embodiment, the first electrode EL1 may have a first polarity, and the second electrode EL2 may have a second polarity opposite to the first polarity. For example, the first polarity may have a positive polarity and the second polarity may have a negative polarity, but is not limited thereto, and the first polarity may have a negative polarity and the second polarity may have a positive polarity.

In an embodiment, in case that the first electrode EL1 and the second electrode EL2 are connected to a power source (not shown), electrostatic force may be generated in the plurality of electrostatic chucks ESC. In an embodiment, the plurality of electrostatic chucks ESC may generate an electrostatic force, and an attractive force may be generated between the substrate SUB and the plurality of electrostatic chucks ESC by the electrostatic force. Accordingly, the substrate SUB may be in contact with lower surfaces of the plurality of electrostatic chucks ESC and be fixed by the plurality of electrostatic chucks ESC. The substrate SUB may be fixed in contact with lower surfaces of the plurality of electrostatic chucks ESC by electrostatic force generated from the plurality of electrostatic chucks ESC.

In an embodiment, the plurality of electrostatic chucks ESC may include a first electrostatic chuck ESC1, a second electrostatic chuck ESC2, and a third electrostatic chuck ESC3. The first electrostatic chuck ESC1, the second electrostatic chuck ESC2, and the third electrostatic chuck ESC3 may be disposed to be spaced apart from each other in the first direction DR1. The substrate SUB may be fixed by the first electrostatic chuck ESC1, the second electrostatic chuck ESC2, and the third electrostatic chuck ESC3. Referring to FIG. 1, the substrate SUB is illustrated as being fixed by the first electrostatic chuck ESC1, the second electrostatic chuck ESC2, and the third electrostatic chuck ESC3, but is not limited thereto. For example, the number of the plurality of electrostatic chucks ESC for fixing the substrate SUB may be changed to corresponds to a size of the substrate SUB and a requirement (or design condition) of a display panel manufactured by the substrate SUB.

In an embodiment, by disposing the plurality of electrostatic chucks ESC supporting the substrate SUB on the lower surface of the plate PT, a force due to gravity may be dispersed to each of the plurality of electrostatic chucks ESC, thereby preventing the plurality of electrostatic chucks ESC from being sagging downward by gravity.

In an embodiment, the plurality of electrostatic chucks ESC disposed in the middle of the plurality of electrostatic chucks ESC may be formed of a material different from the plurality of electrostatic chucks ESC disposed at both ends of the plate PT. In an embodiment, the first electrostatic chuck ESC1 and the third electrostatic chuck ESC3 of the plurality of electrostatic chucks ESC may be formed of a metal material, and the second electrostatic chuck ESC2 disposed between the first electrostatic chuck ESC1 and the third electrostatic chuck ESC3 may be formed of a ceramic material.

As the size of the plurality of electrostatic chucks ESC is increased, the force due to gravity may be relatively concentrated on the second electrostatic chuck ESC2 disposed in the middle of the plate PT. For example, the flatness of the second electrostatic chuck ESC2 may be less than that of the first electrostatic chuck ESC1 and the third electrostatic chucks ESC3 connected or coupled to both ends of the plate PT. To improve the flatness of the second electrostatic chuck ESC2, the second electrostatic chuck ESC2 may be formed of a ceramic material, and the first electrostatic chuck ESC1 and the third electrostatic chuck ESC3 may be formed of a metal material.

In an embodiment, the substrate SUB may be fixed to the lower portion of the plurality of electrostatic chucks ESC in a flat state by controlling the flatness between the plurality of electrostatic chucks ESC.

In an embodiment, each of the plurality of electrostatic chucks ESC may include a plurality of driving shafts DAX. The plurality of driving shafts DAX may be disposed between the plurality of electrostatic chucks ESC and the plate PT to connect or couple the plurality of electrostatic chucks ESC and the plate PT.

In an embodiment, the plurality of driving shafts DAX may be disposed to pass through an area of an edge of the first surface S1. The plurality of driving shafts DAX may be disposed to pass through one area or an area of the plurality of electrostatic chucks ESC corresponding to an edge portion of the substrate SUB and one area or an area of the plate PT corresponding to the edge portion of the substrate SUB.

In an embodiment, the deposition apparatus 100 may control the flatness between the plurality of electrostatic chucks ESC by individually controlling the plurality of driving shafts DAX connected or coupled to each of the plurality of electrostatic chucks ESC.

In an embodiment, a length of the plurality of driving shafts DAX may be increased or decreased in the longitudinal direction (for example, the second direction DR2).

In an embodiment, each of the plurality of electrostatic chucks ESC may include a sensor SM. In an embodiment, the sensor SM may be exposed through one area or an area of the second surface S2 of the plurality of electrostatic chucks ESC. The sensor SM may detect a contact with the substrate SUB. In an embodiment, the deposition apparatus 100 may determine a height deviation between the plurality of electrostatic chucks ESC based on the contact with the substrate SUB sensed by the sensor SM.

In an embodiment, the sensor SM may include materials whose resistance changes in response to an applied pressure. The sensor SM may include, for example, piezo-electric materials, carbon powder, quantum tunnelling composite (QTC), silver nanoparticles, single crystal or polycrystalline silicon, carbon nanotubes, graphene, or the like within the spirit and the scope of the disclosure.

In an embodiment, the deposition mask DMK may be disposed under or below the substrate support SP. The deposition mask DMK may be disposed on the mask frame MF.

In an embodiment, the deposition mask DMK may have a rectangular shape having side surfaces extending in the first direction DR1 and side surfaces extending in the third direction DR3, but a shape of the deposition mask DMK is not limited thereto. It is to be understood that the shapes disclosed herein may also include shapes substantial to the shapes disclosed herein.

In an embodiment, the deposition mask DMK may include a plurality of openings OP spaced apart from each other in the first direction DR1. The shape and number of the plurality of openings OP formed in the deposition mask DMK may be changed according to conditions of treating process of the substrate SUB.

In an embodiment, the mask frame MF may have a shape having side surfaces extending in the first direction DR1 and side surfaces extending in the third direction DR3 crossing (or intersecting) the first direction DR1. The mask frame MF may have a shape of a rectangular frame, but the shape of the mask frame MF is not limited thereto. In an embodiment, the deposition mask DMK may be fixedly connected or coupled to the mask frame MF.

In an embodiment, the transfer unit MOV may be disposed on the plate PT. The transfer unit MOV may be connected to an upper portion of the plate PT to vertically reciprocate. The substrate SUB chucked by the plurality of electrostatic chucks ESC may move toward the deposition mask DMK by the vertical reciprocating movement of the transfer unit MOV.

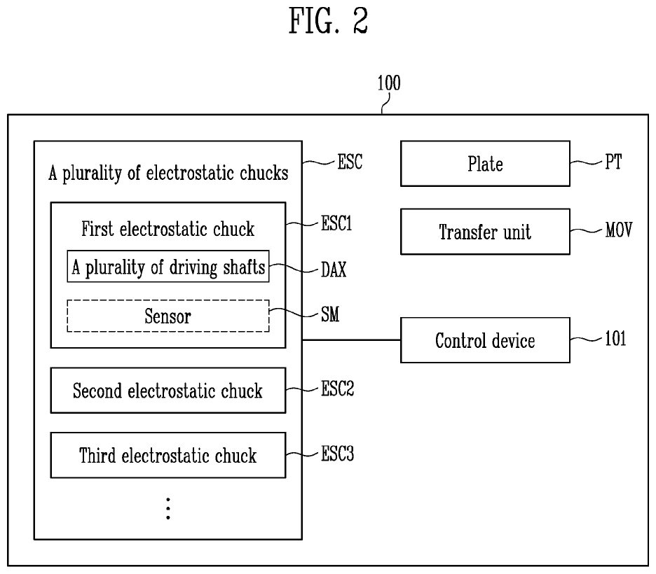

FIG. 2 illustrates configurations of the deposition apparatus of FIG. 1.

Referring to FIG. 2, the deposition apparatus 100 may include a plate PT, a plurality of electrostatic chucks ESC, a transfer unit MOV, and a control device 101.

In an embodiment, the plate PT may be connected or coupled to the plurality of electrostatic chucks ESC through a plurality of driving shafts DAX. The plate PT may be connected or coupled to the transfer unit MOV.

In an embodiment, the deposition apparatus 100 may reciprocate in the vertical direction through the transfer unit MOV.

In an embodiment, the plurality of electrostatic chucks ESC may include a plurality of electrostatic chucks for fixing a substrate (for example, the substrate SUB of FIG. 1). In an embodiment, the plurality of electrostatic chucks ESC may include a first electrostatic chuck ESC1, a second electrostatic chuck ESC2, a third electrostatic chuck ESC3, . . . , and an N-th electrostatic chuck.

In an embodiment, each of the plurality of electrostatic chucks ESC may include a plurality of driving shafts DAX. In an embodiment, the plurality of driving shafts DAX may be disposed in the plurality of electrostatic chucks ESC to avoid components necessary for a process of treating a substrate (for example, the substrate SUB of FIG. 1).

In an embodiment, the plurality of driving shafts DAX may be disposed between the plurality of electrostatic chucks ESC and the plate PT. The plurality of driving shafts DAX may be disposed through one surface or a surface of an edge of each of the plurality of electrostatic chucks ESC.

In an embodiment, lengths of the plurality of driving shafts DAX may be controlled in the longitudinal direction by the control device 101. In an embodiment, the plurality of driving shafts DAX may include at least one of an elastic member and a driving motor. The elastic member may include at least one of a leaf spring, a coil spring, and a wire spring.

In an embodiment, each of the plurality of electrostatic chucks ESC may include a sensor SM. The sensor SM may be disposed on one surface or a surface of the plurality of electrostatic chucks ESC with which the substrate SUB is in contact.

In an embodiment, the substrate SUB in contact with the plurality of electrostatic chucks ESC may be sensed through the sensor SM disposed on each of the plurality of electrostatic chucks ESC. In an embodiment, in case that the plurality of electrostatic chucks ESC include the first electrostatic chuck ESC1, the second electrostatic chuck ESC2, and the third electrostatic chuck ESC3, the sensor SM disposed on the first electrostatic chuck ESC1 may sense the substrate SUB contacting the first electrostatic chuck ESC1, the sensor SM disposed on the second electrostatic chuck ESC2 may sense the substrate SUB contacting the second electrostatic chuck ESC2, and the sensor SM disposed on the third electrostatic chuck ESC3 may sense the substrate SUB contacting the third electrostatic chuck ESC3.

In an embodiment, the deposition apparatus 100 may include a control device 101 electrically connected to the sensor SM and the plurality of driving shafts DAX to control the flatness between the plurality of electrostatic chucks ESC.

In an embodiment, the control device 101 may sense the contact with the substrate SUB with respect to each of the plurality of electrostatic chucks ESC through the sensor SM to measure the height deviation between the plurality of electrostatic chucks ESC. In an embodiment, the control device 101 may measure the height deviation between the plurality of electrostatic chucks ESC based on the order in which the substrate SUB is contacted with respect to each of the plurality of electrostatic chucks ESC.

For example, after the contact with the substrate SUB with respect to the second electrostatic chuck ESC2 is sensed through the sensor SM disposed on the second electrostatic chuck ESC2, the contact with the substrate SUB with respect to the first electrostatic chuck ESC1 and the third electrostatic chuck ESC3 may be simultaneously sensed through the sensor SM disposed on the first electrostatic chuck ESC1 and the third electrostatic chuck ESC3. The control device 101 may measure the height deviation between the first electrostatic chuck ESC1, the second electrostatic chuck ESC2, and the third electrostatic chuck ESC3 based on a contact timing with the substrate SUB with respect to the second electrostatic chuck ESC2 and a contact timing with the substrate SUB with respect to the first electrostatic chuck ESC1 and the third electrostatic chuck ESC3.

In an embodiment, the height deviation between the plurality of electrostatic chucks ESC may be determined based on a distance spaced apart from one surface or a surface or a virtual surface of the plate PT. A distance from one surface or a surface of the plate PT to the second electrostatic chuck ESC2 may be longer than a distance from one surface or a surface of the plate PT to the first electrostatic chuck ESC1 and the third electrostatic chuck ESC3.

In an embodiment, the control device 101 may control the flatness between the plurality of electrostatic chucks ESC through the plurality of driving shafts DAX based on the height deviation between the plurality of electrostatic chucks ESC. For example, in case that the second electrostatic chuck ESC2 among the first electrostatic chuck ESC1, the second electrostatic chuck ESC2, and the third electrostatic chuck ESC3 has the height deviation in relation to the first electrostatic chuck ESC1 and the third electrostatic chuck the ESC3, the control device 101 may control the plurality of driving shafts DAX included in the second electrostatic chuck ESC2 to control the flatness between the first electrostatic chuck ESC1, the second electrostatic chuck ESC2, and the third electrostatic chuck ESC3. In an embodiment, the flatness between the first electrostatic chuck ESC1, the second electrostatic chuck ESC2, and the third electrostatic chucks ESC3 may be controlled by controlling the plurality of driving shafts DAX included in the first electrostatic chuck ESC1 and the third electrostatic chuck ESC3.

In an embodiment, the control device 101 may control the flatness between the plurality of electrostatic chucks ESC and may perform a process (for example, a deposition process or an etching process) for treating the substrate SUB. For example, while the substrate SUB is fixed in a flat state by the plurality of electrostatic chucks ESC by controlling the flatness between the plurality of electrostatic chucks ESC, a process of treating the substrate SUB by the deposition apparatus 100 may be performed.

In an embodiment, the control device 101 may be electrically connected to the transfer unit MOV. After controlling the flatness between the plurality of electrostatic chucks ESC, the control device 101 may control the transfer unit MOV to dispose the substrate SUB to be adjacent to the deposition mask (for example, the deposition mask DMK of FIG. 1).

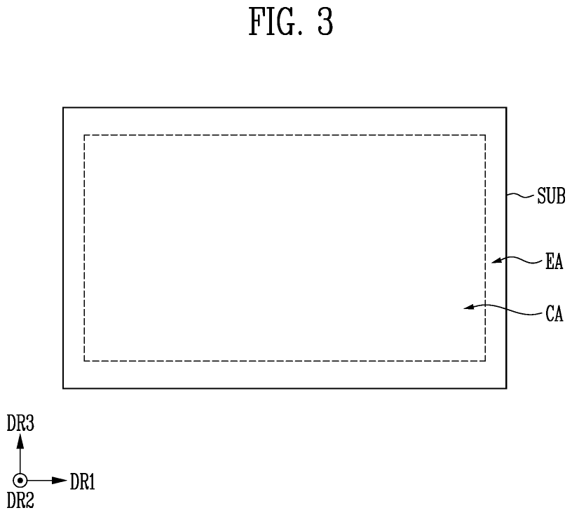

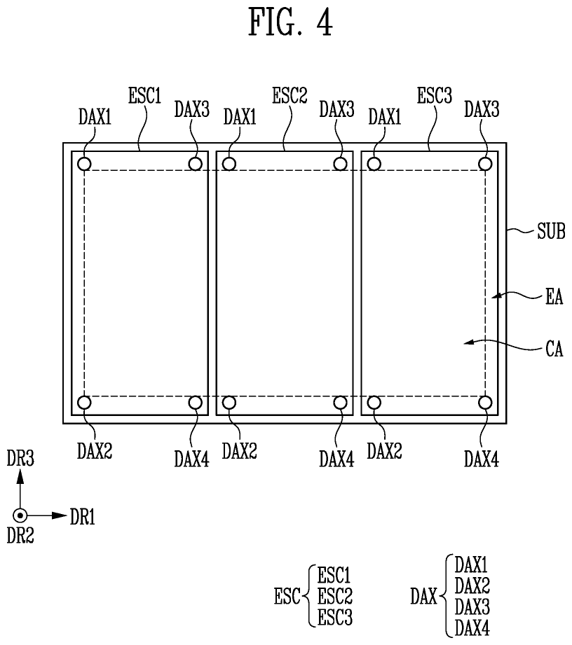

FIG. 3 is a drawing illustrating an example of a substrate of FIG. 1. FIG. 4 illustrates an example of a plurality of electrostatic chucks of FIG. 1.

FIG. 3 is a drawing for illustrating a center area CA and an edge area EA of the substrate SUB, and FIG. 4 is a drawing for illustrating an area in which the plurality of driving shafts DAX are disposed based on the substrate SUB.

Referring to FIG. 3, the substrate SUB may include the center area CA and the edge area EA disposed outside the center area CA.

In an embodiment, the substrate SUB may be a portion of a display panel including a light emitting element. The substrate SUB may have a surface parallel to a surface defined by the first direction DR1 and the third direction DR3. The thickness direction of the substrate SUB may be indicated by the second direction DR2. The substrate SUB may include a pixel defining layer that partitions a light emitting area between pixels, an electrode, a pixel circuit layer, and the like within the spirit and the scope of the disclosure.

In an embodiment, the center area CA of the substrate SUB may include an area requiring a treating process. The edge area EA of the substrate SUB may correspond to an area that does not require a treating process.

Referring to FIG. 4, the substrate SUB may be disposed under or below the plurality of electrostatic chucks ESC. The plurality of driving shafts DAX may be disposed on the plurality of electrostatic chucks ESC.

In an embodiment, the plurality of electrostatic chucks ESC may include the first electrostatic chuck ESC1, the second electrostatic chuck ESC2, and the third electrostatic chuck ESC3 sequentially spaced apart in the first direction DR1.

In an embodiment, the substrate SUB may be fixed by an electrostatic force formed by the first electrostatic chuck ESC1, the second electrostatic chuck ESC2, and the third electrostatic chuck ESC3.

In an embodiment, the plurality of driving shafts DAX may be disposed on each of the plurality of electrostatic chucks ESC. For example, each of the first electrostatic chuck ESC1, the second electrostatic chuck ESC2, and the third electrostatic chuck ESC3 may include a plurality of driving shafts DAX.

In an embodiment, the plurality of driving shafts DAX may be disposed through one area or an area of the plurality of electrostatic chucks ESC corresponding to the edge area EA of the substrate SUB.

In an embodiment, the plurality of driving shafts DAX or DAX′ may include a first driving shaft DAX1, a second driving shaft DAX2, a third driving shaft DAX3, and a fourth driving shaft DAX4. In an embodiment, each of the first electrostatic chuck ESC1, the second electrostatic chuck ESC2, and the third electrostatic chuck ESC3 may include the first driving shaft DAX1, the second driving shaft DAX2, the third driving shaft DAX3, and the fourth driving shaft DAX4.

In an embodiment, the third and fourth driving shafts DAX3 and DAX4 included in the first electrostatic chuck ESC1 and the first and second driving shafts DAX1 and DAX2 included in the second electrostatic chuck ESC2 may be disposed adjacent to the second electrostatic chuck ESC2.

In an embodiment, the plurality of driving shafts DAX may be individually driven. In an embodiment, the first driving shaft DAX1, the second driving shaft DAX2, the third driving shaft DAX3, and the fourth driving shaft DAX4 included in the first electrostatic chuck ESC1 may be individually driven.

In an embodiment, the deposition apparatus may control the flatness between the plurality of electrostatic chucks ESC by individually driving the plurality of driving shafts DAX to compensate for the height deviation between the plurality of electrostatic chucks ESC.

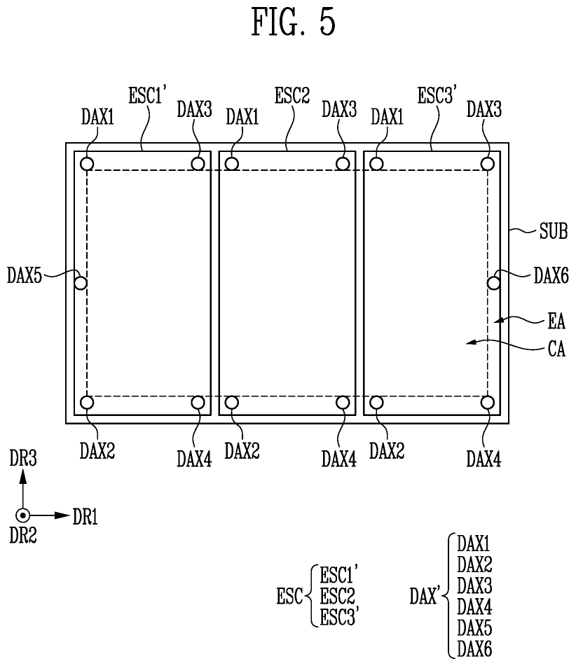

FIG. 5 illustrates another example of a plurality of electrostatic chucks of FIG. 1.

In an embodiment, as an aspect ratio of the substrate SUB decreases, an aspect ratio of the plurality of electrostatic chucks ESC for fixing the substrate SUB may also decrease. The flatness of the first electrostatic chuck ESC1 and the third electrostatic chuck ESC3 disposed at both ends in the first direction DR1 among the plurality of electrostatic chucks ESC may be out of a given range, so that the flatness of the substrate SUB fixed to the electrostatic chuck ESC1 and the third electrostatic chuck ESC3 may also be affected.

In an embodiment, the first electrostatic chuck ESC1′ and the third electrostatic chuck ESC3′ may further include a driving shaft in consideration of the aspect ratio of each of the plurality of electrostatic chucks ESC. For example, the first electrostatic chuck ESC1 may further include a fifth driving shaft DAX5 between the first driving shaft DAX1 and the second driving shaft DAX2. The third electrostatic chuck ESC3′ may further include a sixth driving shaft DAX6 between the third driving shaft DAX3 and the fourth driving shaft DAX4.

In an embodiment, the first electrostatic chuck ESC1′ and the third electrostatic chuck ESC3′ further include a driving shaft in one area or an area corresponding to the edge area EA of the substrate SUB extending in the third direction DR3, so that the flatness of the first electrostatic chuck ESC′ and the third electrostatic chuck ESC3′ may be improved.

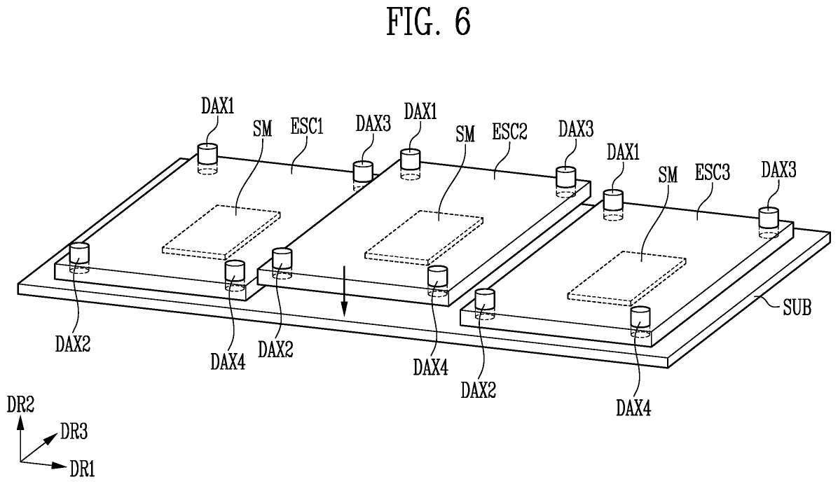

FIG. 6 is a drawing for illustrating a method of controlling flatness of a plurality of electrostatic chucks of FIG. 1.

Referring to FIG. 6, the plurality of electrostatic chucks ESC may chuck (or fix) or dechuck the substrate SUB using electrostatic force. The plurality of electrostatic chucks ESC may fix the substrate SUB to perform a process of treating the substrate SUB.

In an embodiment, in the process of fixing the substrate SUB to the plurality of electrostatic chucks ESC, the deposition apparatus may sense the contact with the substrate SUB through the sensor SM included in the plurality of electrostatic chucks ESC.

Referring to FIG. 6, in case that the second electrostatic chuck ESC2 has a height deviation from the first electrostatic chuck ESC1 and the third electrostatic chuck ESC3, a contact with the substrate SUB with respect to the first electrostatic chuck ESC1 and the third electrostatic chuck ESC3 may be first sensed by the sensor SM included in the first electrostatic chuck ESC1 and the third electrostatic chuck ESC3. After the contact with the substrate SUB with respect to the first electrostatic chuck ESC1 and the third electrostatic chuck ESC3 is sensed, the contact with the substrate SUB with respect to the second electrostatic chuck ESC2 may be sensed. The substrate SUB may be fixed in a non-planar state by shapes of the first electrostatic chuck ESC1, the second electrostatic chuck ESC2, and the third electrostatic chuck ESC3.

In an embodiment, the deposition apparatus may measure the height deviation between the plurality of electrostatic chucks ESC based on the contact order with the substrate SUB with respect to the plurality of electrostatic chucks ESC. Referring to FIG. 6, a distance at which the second electrostatic chuck ESC2 is spaced apart from one virtual plane (for example, one plane of the plate PT of FIG. 1) on the plurality of electrostatic chucks ESC may be less than a distance at which the electrostatic chuck ESC1 and the third electrostatic chuck ESC3 is spaced apart from one virtual plane (for example, one plane of the plate PT of FIG. 1).

In an embodiment, the deposition apparatus may control the flatness between the plurality of electrostatic chucks ESC by correcting the height deviation between the plurality of electrostatic chucks ESC through the plurality of driving shafts DAX. For example, the deposition apparatus may compensate for the height deviation between the first electrostatic chuck ESC1 and the third electrostatic chuck ESC3 by increasing the lengths of the plurality of driving shafts DAX disposed on the second electrostatic chuck ESC2.

In an embodiment, the substrate SUB may be fixed to the lower portion of the plurality of flat electrostatic chucks ESC by controlling the flatness between the plurality of electrostatic chucks ESC, thereby preventing mass production of defective substrates or poor quality substrates due to an error with respect to the flatness of the substrate SUB in the process of treating the substrate SUB.

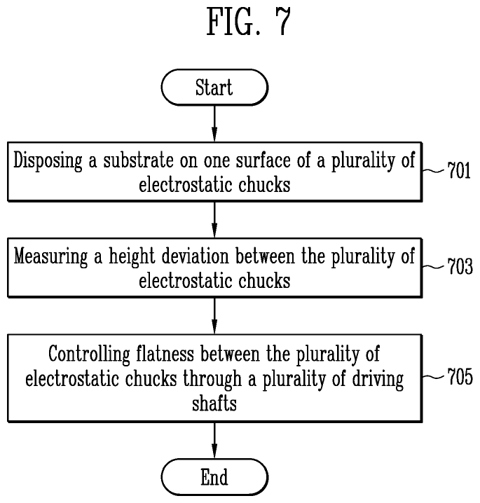

FIG. 7 is a flowchart illustrating a driving method of the deposition apparatus of FIG. 1.

The deposition apparatus 100 (for example, the control device 101 of FIG. 2) according to an embodiment of the disclosure may dispose a substrate (for example, the substrate SUB of FIG. 1) to one surface or a surface of the plurality of electrostatic chucks ESC in operation 701.

In an embodiment, the plurality of electrostatic chucks ESC may adsorb the substrate SUB through an electrostatic force formed using an electrostatic induction phenomenon.

According to an embodiment, the deposition apparatus 100 (for example, the control device 101 of FIG. 2) may measure a height deviation between the plurality of electrostatic chucks ESC in operation 703.

In an embodiment, each of the plurality of electrostatic chucks ESC may include a sensor (for example, the sensor SM of FIG. 2). In an embodiment, the sensor SM may be exposed on one surface or a surface that the substrate SUB contacts. The control device 101 may sense the contact with the substrate SUB through the sensor SM. The height deviation between the plurality of electrostatic chucks ESC may be measured through the contact order with the substrate SUB between the plurality of electrostatic chucks ESC.

In an embodiment, the control device 101 may determine the height deviation between the plurality of electrostatic chucks ESC through the order with which the substrate SUB is contacted between the plurality of electrostatic chucks ESC because the plurality of electrostatic chucks ESC have a constant speed adjacent to the substrate SUB.

According to an embodiment, the deposition apparatus 100 (for example, the control device 101 of FIG. 2) may control the flatness between the plurality of electrostatic chucks ESC through a plurality of driving shafts based on the height deviation between the plurality of electrostatic chucks ESC in operation 705.

In an embodiment, the control device 101 may control the flatness between the plurality of electrostatic chucks ESC by individually controlling the plurality of driving shafts DAX disposed in the edge area of the plurality of electrostatic chucks ESC based on the height deviation between the plurality of electrostatic chucks ESC.

In an embodiment, a process of treating the substrate SUB may be performed in response to an operation of controlling the flatness between the plurality of electrostatic chucks ESC. In an embodiment, the deposition apparatus 100 may move the substrate SUB to be adjacent to the deposition mask (for example, the deposition mask DMK of FIG. 1) through a transfer unit (for example, the transfer unit MOV of FIG. 1).

In an embodiment, the number of the plurality of driving shafts DAX included in each of the plurality of electrostatic chucks ESC may be the same, but may change depending on the size of the substrate SUB and conditions according to the treating process of the substrate SUB. For example, electrostatic chucks disposed at both ends of the plurality of electrostatic chucks ESC among the plurality of electrostatic chucks ESC, may further include the driving shaft than electrostatic chucks disposed in the middle thereof.

The deposition apparatus and the driving method thereof according to embodiments can prevent the electrostatic chucks from sagging in the gravitational direction by fixing the substrate through a plurality of electrostatic chucks, thereby fixing the substrate in the flat state without deformation of the shape. Also, by measuring the height deviation between the plurality of electrostatic chucks and compensating for the height deviation between the plurality of electrostatic chucks through the plurality of driving shafts included in the plurality of electrostatic chucks, the flatness between the plurality of electrostatic chucks can be controlled. As a result, the process of treating the substrate may be performed while the substrate is maintained in a flat state regardless of a change in process conditions.

The deposition apparatus and the driving method thereof according to embodiments may prevent mass production of defective substrates or poor quality substrates due to an error with respect to the flatness of the substrate in the process of treating the substrate.

Although the above has been described with reference to embodiments of the disclosure, those skilled in the art will understand that various modifications and changes can be made to the disclosure without departing from the spirit and scope of the disclosure as set forth in the claims.

What is claimed is:

1. A deposition apparatus comprising:
a plate;
a plurality of electrostatic chucks including:
a first surface on which the plate is disposed; and
a second surface on which a substrate is supported; and
a control device that controls a flatness between the plurality of electrostatic chucks, wherein
each of the plurality of electrostatic chucks includes a plurality of driving shafts disposed through an area of an edge of the first surface of each of the plurality of electrostatic chucks, and
the control device controls the flatness between the plurality of electrostatic chucks through the plurality of driving shafts by measuring a height deviation between the plurality of electrostatic chucks.

2. The deposition apparatus of claim 1, wherein
the plurality of electrostatic chucks includes a first electrostatic chuck, a second electrostatic chuck, and a third electrostatic chuck spaced apart from each other in a first direction,
the first electrostatic chuck and the third electrostatic chuck include a metal material, and
the second electrostatic chuck includes a ceramic material.

3. The deposition apparatus of claim 2, wherein
the first electrostatic chuck, the second electrostatic chuck, and the third electrostatic chuck support the substrate including a center area and an edge area surrounding the center area, and
the plurality of driving shafts are disposed on the first surface of each of the first electrostatic chuck, the second electrostatic chuck, and the third electrostatic chuck corresponding to the edge area of the substrate.

4. The deposition apparatus of claim 3, wherein
the plurality of driving shafts include a first driving shaft, a second driving shaft, a third driving shaft, and a fourth driving shaft, and
the third driving shaft and the fourth driving shaft disposed on the first electrostatic chuck and the first driving shaft and the second driving shaft disposed on the third electrostatic chuck are adjacent to the second electrostatic chuck.

5. The deposition apparatus of claim 4, wherein
the first electrostatic chuck further includes a fifth driving shaft disposed between the first driving shaft and the second driving shaft, and
the third electrostatic chuck further includes a sixth driving shaft disposed between the third driving shaft and the fourth driving shaft.

6. The deposition apparatus of claim 3, further comprising:
a mask frame disposed in an area corresponding to the edge area below the substrate; and
a deposition mask corresponding to the center area below the substrate.

7. The deposition apparatus of claim 3, further comprising:
a transfer unit that is connected to an area of the plate corresponding to the center area of the substrate and that controls a vertical movement of the plurality of electrostatic chucks, wherein
the plurality of driving shafts pass through at least a portion of the plate while avoiding an area that includes the transfer unit.

8. The deposition apparatus of claim 4, wherein each of the plurality of driving shafts is individually driven by the control device.

9. The deposition apparatus of claim 1, wherein
each of the plurality of electrostatic chucks further includes a sensor exposed through the second surface of the plurality of electrostatic chucks,
the sensor detects a contact with the substrate, and
the control device measures a height deviation between the plurality of electrostatic chucks based on a contact order with the substrate with respect to each of the plurality of electrostatic chucks.

10. The deposition apparatus of claim 9, wherein the control device controls the plurality of driving shafts so that the plurality of electrostatic chucks are spaced apart from each other by a same distance based on a surface of the plate based on the height deviation between the plurality of electrostatic chucks.

11. A driving method of a deposition apparatus comprising:
disposing a substrate on a surface of a plurality of electrostatic chucks;
measuring a height deviation between the plurality of electrostatic chucks; and
controlling a flatness between the plurality of electrostatic chucks through a plurality of driving shafts disposed on each of the plurality of electrostatic chucks based on the height deviation between the plurality of electrostatic chucks, wherein
the plurality of driving shafts are disposed in an area of an edge of another surface of the plurality of electrostatic chucks facing the surface of the plurality of electrostatic chucks.

12. The driving method of claim 11, wherein
each of the plurality of electrostatic chucks further includes a sensor disposed on the surface of the plurality of electrostatic chucks, and
the measuring of the height deviation between the plurality of electrostatic chucks includes:
detecting a contact with the substrate with respect to each of the plurality of electrostatic chucks through the sensor; and
determining the height deviation between the plurality of electrostatic chucks based on a contact order with the substrate with respect to each of the plurality of electrostatic chucks.

13. The driving method of claim 11, wherein the plurality of driving shafts disposed on each of the plurality of electrostatic chucks are individually driven in the controlling of the flatness between the plurality of electrostatic chucks.

14. The driving method of claim 11, wherein
the plurality of driving shafts are disposed between the plurality of electrostatic chucks and a plate, and
a distance between the plurality of electrostatic chucks from the plate is equally controlled through the plurality of driving shafts in the controlling of the flatness between the plurality of electrostatic chucks.

15. The driving method of claim 11, wherein
the plurality of electrostatic chucks includes a first electrostatic chuck, a second electrostatic chuck, and a third electrostatic chuck spaced apart from each other in a first direction, and
the first electrostatic chuck and the third electrostatic chuck include a metal material and the second electrostatic chuck includes a ceramic material.

16. The driving method of claim 15, wherein
the substrate including a center area and an edge area surrounding the center area is absorbed by applying a voltage to the first electrostatic chuck, the second electrostatic chuck, and the third electrostatic chuck in the disposing of the substrate on the surface of the plurality of electrostatic chucks.

17. The driving method of claim 16, wherein the plurality of driving shafts are disposed on the another surface of each of the first electrostatic chuck, the second electrostatic chuck, and the third electrostatic chuck corresponding to the edge area of the substrate.

18. The driving method of claim 17, wherein
the plurality of driving shafts include a first driving shaft, a second driving shaft, a third driving shaft, and a fourth driving shaft, and
the third driving shaft and the fourth driving shaft disposed on the first electrostatic chuck and the first driving shaft and the second driving shaft disposed on the third electrostatic chuck are adjacent to the second electrostatic chuck.

19. The driving method of claim 18, wherein
the first electrostatic chuck further includes a fifth driving shaft disposed between the first driving shaft and the second driving shaft, and
the third electrostatic chuck further includes a sixth driving shaft disposed between the third driving shaft and the fourth driving shaft.

20. The driving method of claim 11, further comprising:
moving the substrate to be adjacent to a deposition mask corresponding to the controlling of the flatness between the plurality of electrostatic chucks.
